(19) United States
(12) Patent Application Publication
(10) Pub. No.: US 2006/0284216 A1
(43) Pub. Date: Dec. 21, 2006

(54) Method for producing optical film and apparatus for producing the same

(75) Inventors: Hiroaki Mizushima, Ibaraki-shi (JP); Shouji Shibata, Ibaraki-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NITTO DENKO CORPORATION, Ibaraki-shi (JP)

(21) Appl. No.: 11/452,949

(22) Filed: Jun. 15, 2006

(30) Foreign Application Priority Data
Jun. 20, 2005 (JP) 2005-179461

(51) Int. Cl. H01L 27/20

(52) U.S. Cl. 257/254

(57) ABSTRACT

Disclosed herein is a method for producing an optical film, comprising carrying out a given process by allowing a film having a joint to continuously pass through the given process while meandering the film to increase the length of a film transport path, wherein when the joint of the film passes through a given position in the given process, the film transport path is made straight to allow the joint to pass through the given position without meandering the film.

### FIELD OF THE INVENTION

The present invention relates to a method for producing an optical film such as a polarizing plate or a retardation film, an apparatus to be used for producing such an optical film, and an optical film obtained by the production method.

### BACKGROUND OF THE INVENTION

As the demand for liquid crystal displays grows and cost reduction is required, improvements in productivity and yield of optical films to be used for liquid crystal displays are of increasing importance. Generally, an optical film is produced by subjecting a raw film unwound from a roll thereof to processing and then winding it up. Such a raw film has a certain length, and therefore when the raw film is exhausted, a new raw film needs to be threaded through an apparatus for producing an optical film. However, such a production apparatus has a plurality of rollers to provide a complicated film transport path along which the raw film can meander up and down. Therefore, it takes a lot of effort (labor) to thread a new raw film through the production apparatus having such a complicated film transport path every time a roll of raw film is switched to new one.

In order to reduce the load of such troublesome work, for example, Japanese Patent Laid-open No. 2001-228594 has disclosed a device for transporting a roll film which comprises a first roller train having a plurality of rollers, a second roller train having a plurality of rollers arranged under the first roller train, and a lifting device for raising or lowering the second roller train from a state where the second roller train is positioned above the first roller train to a state where the second roller train is positioned under the first roller train. Japanese Patent Laid-open No. 2001-228594 describes that the use of such a film transport device reduces the workload of film threading.

Generally, when a roll of raw film is switched to new one, adjacent sheets of the raw film are joined end to end with, for example, a pressure-sensitive adhesive tape to allow continuous production of a film. In a case where such a method is applied to the film transport device described above, there is a possibility that a joint between adjacent sheets of the raw film (hereinafter, also simply referred to as a “joint”) is separated or broken due to, for example, tension applied to the raw film when the joint passes through a treatment process. Further, there is also a possibility that the pressure-sensitive adhesive tape used in the joint is eluted, thereby causing contamination of the rollers. These phenomena will cause a problem that productivity, equipment availability, and yield are reduced.

Such a problem becomes particularly conspicuous in producing an optical film such as a polarizing film. In production of a polarizing film, a polyvinyl alcohol film is used as a raw film.

When adjacent sheets of a polyvinyl alcohol film are joined end to end with, for example, a pressure-sensitive adhesive tape, there is a problem that a joint between adjacent sheets of the film is likely to separate when passing through a bath solution for treatment, thereby causing contamination of the bath solution and the rollers.

Further, in a drying process, there is a case where the joint is broken due to curing. As a result, a problem arises that it becomes difficult to continuously produce an optical film even when film threading is automatically carried out.

### SUMMARY OF THE INVENTION

Considering the above problems, an object of the present invention is to provide a method for producing an optical film which can improve productivity, equipment availability, and yield, an apparatus to be used for producing an optical film, and an optical film obtained by the production method.

The present inventors have found that the following system can solve the problems described above, which has led to the completion of the present invention.

In order to solve the problems described above, the present invention is directed to a method for producing an optical film, comprising carrying out a given process by allowing a film having a joint to continuously pass through the given process while meandering the film to extend the length of a film transport path, wherein when the joint passes through a given position in the given process, the film transport path is made straight to allow the joint to pass through the given position without meandering the film.

As described above, according to the production method of the present invention, when the joint passes through the given position in the given process, the film transport path is made straight to allow the joint to pass through the given position without meandering the film. Therefore, for example, even when the given process is carried out by immersing the film in a bath solution, it is possible to prevent the bath solution from being contaminated by, for example, a pressure-sensitive adhesive tape used for joining adjacent sheets of the film together. In addition, since the joint is not meandered when passing through the given position, the joint is not brought into contact with part of a production apparatus, thereby preventing the production apparatus from being contaminated by elution of the pressure-sensitive adhesive tape. In general, when the film having the joint is subjected to a drying process, breakage of the joint is likely to occur due to curing. However, according to the present invention, excessive tension is not applied to the film, thereby preventing breakage of the joint.

In the present invention, it is preferred that the film transport path is sequentially made straight just before the joint passes through the given position. Further, it is also preferred that the film is sequentially meandered just after the joint has passed through the given position.

By doing so, it is possible to make the film transport path straight sequentially only when the joint passes through the given position in the given process and to sequentially meander the film just after the joint has passed through the given position, thereby further improving productivity.

Furthermore, it is also preferred that the film is meandered while keeping at least either tension applied to the film or the staying time of the film constant.

By keeping tension applied to the film constant when the film is meandered, it is possible to further prevent the breakage of a joint between adjacent sheets of the film. Further, by keeping the staying time of the film constant, it is possible to prevent variations in processing time of the given process due to up and down movements of an elevating means, thereby allowing an optical film having uniform characteristics to be produced.

Moreover, it is also preferred that the given process is a process of immersion in a solution. Here, a process of immersion in a solution means a process carried out by immersing the film in a given solution, such as a swelling, dyeing, stretching or cross-linking process.

Moreover, it is also preferred that the given process is a drying process. An example of a drying process includes a process of subjecting the film to heat treatment. Generally, when a film is dried, especially when drying is carried out by heat treatment, a joint between adjacent sheets of the film is likely to break due to curing. However, according to the present invention, it is possible to suppress the application of excessive tension to the film also during a drying process carried out by, for example, heat treatment, thereby preventing the breakage of a joint between adjacent sheets of the film.

Moreover, it is also preferred that the process of immersion in a solution includes a dyeing process or a stretching process.

In order to solve the problems described above, another aspect of the present invention is directed to an apparatus for producing an optical film, comprising:

a pair of transport means for transporting in a predetermined direction, a film having a joint between adjacent sheets of the film to allow the film to continuously pass through a given process;

an elevating means which is provided between the pair of transport means and which is moved up or down to meander the film up and down; and

a control means for controlling the up and down movements of the elevating means, wherein when the joint passes through a given position in the given process, the control means moves up or down the elevating means to provide a straight film transport path to allow the joint to pass through the given position without meandering the film, and wherein after the joint has passed through the given position, the control means moves up or down the elevating means to provide a film transport path along which the film is meandered up and down.

A film fed into the given process by the transport means is subjected to predetermined treatment in the given process. The elevating means is moved up or down to meander the film up and down to extend the length of the film transport path, thereby improving productivity. In a case where the film has the joint, the control means moves up or down the elevating means when the joint passes through the given position in the given process to provide the straight film transport path. By doing so, even in a case where, for example, the given process is a process carried out by immersing the film in a bath solution provided in the production apparatus, it is possible to prevent the bath solution from being contaminated by, for example, a pressure-sensitive adhesive tape used for joining adjacent sheets of the film together. In addition, the joint of the film is not brought into contact with the elevating means, thereby preventing the elevating means from being contaminated by elution of, for example, the pressure-sensitive adhesive tape. Further, by making the film transport path straight, it is possible to suppress the application of excessive tension to the film, thereby preventing the breakage of the joint.

In another aspect of the present invention, it is preferred that the control means sequentially moves up or down the elevating means through which the joint of the film is going to pass to provide a straight film transport path. Further, it is also preferred that the control means sequentially moves up or down the elevating means through which the joint of the film has passed to meander the film up and down.

According to such a structure, the control means controls the elevating means to make the film transport path straight sequentially only when the joint of the film passes through the given position in the given process and to sequentially meander the film just after the joint has passed through the given position, thereby further improving productivity.

Furthermore, it is also preferred that the production apparatus further comprises an accumulating means to be used for transporting the film while keeping tension applied to the film and the staying time of the film constant.

By providing the accumulating means, it is possible to further prevent the breakage of the joint of the film. Further, by keeping the staying time of the film constant, it is possible to prevent variations in processing time of the given process due to up and down movements of the elevating means, thereby allowing the optical film having uniform characteristics to be produced.

Moreover, it is also preferred that the elevating means has a curved surface with which the film is to be brought into contact. This makes it possible to reduce resistance between the film and the elevating means, thereby allowing the film to be smoothly transported.

In order to solve the problems described above, yet another aspect of the present invention is directed to an optical film obtained by carrying out a given process by allowing a film having a joint to continuously pass through the given process while meandering the film to extend the length of a film transport path, wherein when the joint of the film passes through a given position in the given process, the film transport path is made straight to allow the joint to pass through the given position without meandering the film, and wherein after the joint has passed through the given position, the film is meandered up and down along the film transport path.

As described above, according to the present invention, when a joint between adjacent sheets of the film passes through the given position in the given process, the film transport path is made straight to allow the joint to pass through the given position without meandering it, thereby preventing separation or breakage of the joint and contamination of the production apparatus. As a result, it is possible to improve productivity and yield and to produce an optical film having uniform characteristics and good appearance.

### BRIEF DESCRIPTION OF THE DRAWINGS

FIG. 1 is a schematic diagram for explaining a method for producing an optical film according to an embodiment of the present invention, which shows a situation where a joint between adjacent sheets of a film is passing through treatment processes;

FIG. 2 is a schematic diagram for explaining the method for producing an optical film, which shows a situation where the joint has just passed through the treatment processes;

FIG. 3 is a schematic diagram for explaining the method for producing an optical film, which shows a situation where the joint is passing through a drying process; and

FIG. 4 is a schematic diagram for explaining the method for producing an optical film, which shows a situation where the joint has just passed through the drying process.

### BEST MODE FOR CARRYING OUT THE INVENTION

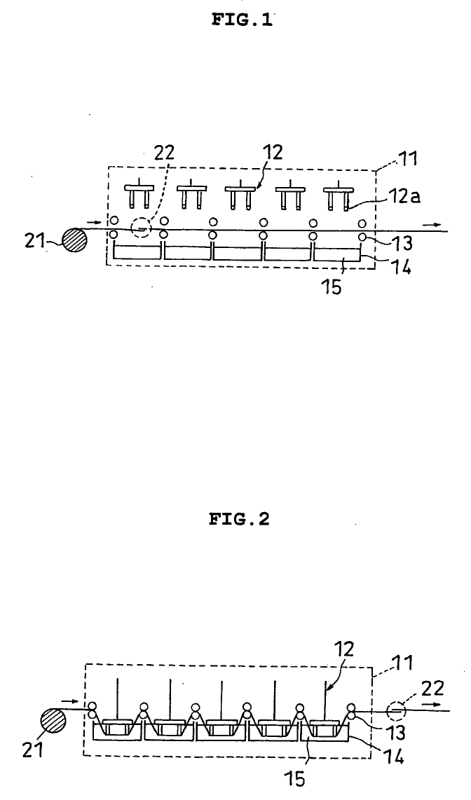

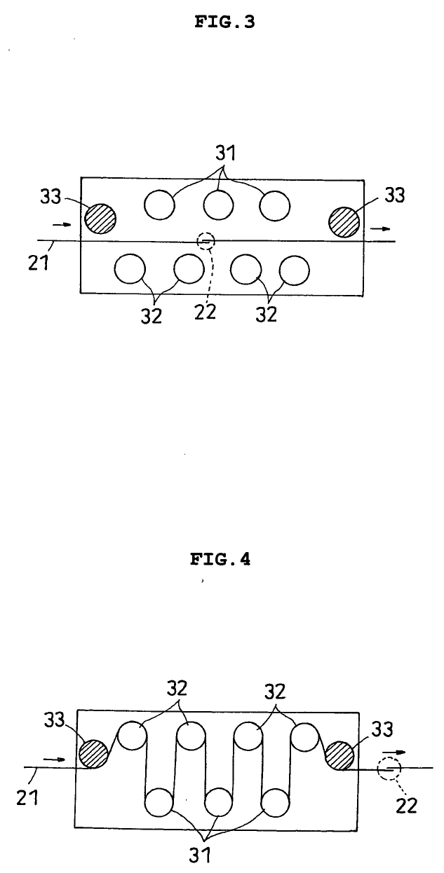

A method for producing an optical film according to the present invention is characterized in that it allows a film having a joint between adjacent sheets of the film to continuously pass through a given process, and that when the joint passes through a given position in the given process, a film transport path is made straight so that the joint can pass through the given position without meandering the film. As described above, the film has a joint because, for example, long sheets of the film are joined end to end with, for example, a pressure-sensitive adhesive tape when a film roll is switched to new one, thereby allowing an optical film to be continuously produced. The production method according to the present invention can be applied to any process. Examples of such a process to which the production method can be applied include, but are not particularly limited to, processes for producing a polarizing film shown in FIGS. 1 and 2 which are carried out by immersing a film in a solution (e.g., swelling, stretching, dyeing, and cross-linking processes) and a drying process shown in FIGS. 3 and 4 (e.g., a heat treatment process). Such treatment, that is, immersion in a solution or heat treatment will cause separation of the joint of the film, and as a result the pressure-sensitive adhesive tape acts as a contamination source. It is to be noted that a pressure-sensitive adhesive tape to be used for joining adjacent sheets of the film together is not particularly limited. A specific example of such the pressure-sensitive adhesive tape includes a double-sided tape manufactured by Nitto Denko Corporation (No. 500).

Hereinbelow, the present invention will be described more specifically with reference to a method for producing a polarizing film. FIG. 1 is a schematic diagram for explaining a method for producing a polarizing film as an example of an optical film, which shows a situation where a joint between adjacent sheets of a film is passing through treatment processes for producing a polarizing film. FIG. 2 is a schematic view for explaining the method for producing a polarizing film, which shows a situation where the joint has just passed through the treatment processes.

As shown in FIG. 1, an optical film production apparatus 11 according to the present invention is used for carrying out various treatment processes, and has a transport means (not shown in the drawings), elevating rolls (elevating means) 12, supporting members 13, and baths 14, and a control means (not shown in the drawings). As described above, the production apparatus 11 has a plurality of baths 14 so that stretching can be carried out in multiple steps.

The transport means has the function of transporting a non-drawn film 21 in the direction of an arrow shown in FIG. 1, and is comprised of, for example, a combination of an exit-side transport roll and an inlet-side transport roll. In transporting the film 21, tension may be applied to the film 21 in a direction parallel to a direction in which the film 21 is transported to keep the film 21 taut. The film 21 is drawn to a predetermined draw ratio by utilizing the difference in circumferential velocity between the exit-side transport roll and the inlet-side transport roll provided per each bath 14.

The elevating roll 12 is provided between the exit-side transport roll and the inlet-side transport roll. When the elevating roll 12 is moved up or down, the film 21 is meandered up and down, and is drawn. The elevating roll 12 includes a roll section 12a for pressing down the film 21, and the roll section 12a is comprised of rolls.

The supporting member 13 is located above the bath 14, and has the function of supporting the film 21 from the lower side. The supporting member 13 is comprised of a roll rotatably borne. Alternatively, the supporting member 13 may be a movable pinch roll to be used together with an upper roll so that the film 21 is pinched by the rolls.

It is to be noted that the roll section 12a of the elevating roll 12 and the supporting member 13 are not limited to those of a roll type, and may be of, for example, a nonrotational and fixed type. Further, the roll section. 12a and the supporting member 13 may have any shape as long as at least their surfaces to be brought into contact with the film 21 are curved. Accordingly, for example, the roll section 12a and the supporting member 13 may have a semicircular, elliptic or fan-like shape in cross section. By allowing the roll section 12a or the supporting member 13 to have such a shape, it is possible to reduce surface frictional resistance caused by contact between the film 21 and the roll section 12a or the supporting member 13, thereby allowing the film 21 to be smoothly transported.

The bath 14 contains a solution 15 required for carrying out each of the treatment processes. Examples of the solution 15 include water and pure water. However, the solution 15 may contain additives required depending on the kind of treatment to be carried out, and the composition of the solution 15 may vary from bath to bath. The bath 14 may have a length of, for example, about 0.5 to 5 m in a direction to which the film 21 is transported.

The control means is used to control up and down movements of the elevating roll 12. More specifically, the control means moves down the elevating roll 12 when the film 21 is drawn, and on the other hand the control means moves up the elevating roll 12 when the joint 22 of the film 21 passes through the treatment process. The elevating roll 12 is moved up or down by, for example, a jack-up system or a hydraulic system.

The production apparatus 11 may further include an accumulating means having the function of keeping the staying time of the film and tension applied to the film constant depending on the tension applied to the film. An example of such an accumulating means to be used in the present invention includes one disclosed in Japanese Patent Laid-open No. Hei 1-197261. Also, it is possible to use an accumulating means obtained by mounting a roll type transport device in a swingable manner so that it can pendulate. The accumulating means is preferably provided upstream of the joint 22 in a direction to which the film 21 is transported. For example, in the case shown in FIG. 1, the accumulating means is preferably provided immediately in front of the production apparatus 11.

As shown in FIG. 1, in a case where the joint 22 between adjacent sheets of the film 21 passes through the treatment processes, the control means moves up all the elevating rolls 12 of the production apparatus 11 to make the transport path of the film 21 straight. By doing so, it is possible to prevent the joint 22 from being immersed in the solution 15 contained in the baths 14, thereby preventing the solution 15 from being contaminated by, for example, a pressure-sensitive adhesive tape used in the joint 22. In addition, it is also possible to prevent the joint 22 from being brought into contact with the elevating rolls 12 and the supporting members 13, thereby preventing them from being contaminated by, for example, the pressure-sensitive adhesive tape. Alternatively, the elevating rolls 12 may be moved up in such a manner that each elevating roll 12 close to the joint 22 between adjacent sheets of the film 21 to be transported is moved up one after another. By doing so, it is possible to further improve productivity.

As shown in FIG. 2, after the joint 22 has passed through the treatment processes, the control means moves down all the elevating rolls 12 to again press down the film 21 and immerse the film 21 in the solution 15 contained in the baths 14 to draw the film 21. The draw ratio of the film is set to a predetermined value. For example, in the case of producing a polarizing film, a draw ratio is preferably set to about 1.5 to 3 times the original length of the film 21. It is to be noted that the elevating rolls 12 may be moved down in such a manner that each elevating roll 12 through which the joint 22 has passed is moved down one after another. By doing so, it is possible to further improve productivity.

If necessary, the production apparatus according to the present invention may appropriately include additional components to carry out the treatment processes. For example, in the drying process shown in FIGS. 3 and 4, upper elevating rolls 31 and lower elevating rolls 32 are provided between a pair of supporting members 33. As shown in FIG. 3, in a case where the joint 22 between adjacent sheets of the film 21 passes through the drying process, the upper elevating rolls 31 are located above the film 21 and the lower elevating rolls 32 are located under the film 21. After the joint 22 has passed through the drying process, as shown in FIG. 4, the upper elevating rolls 31 are moved down and the lower elevating rolls 32 are moved up to extend the length of the transport path of the film 21, thereby enhancing drying efficiency. The up and down movements of the upper elevating rolls 31 and the lower elevating rolls 32 are controlled by a control means (not shown in the drawings). Further, the above-described accumulating means may also be provided. By providing the accumulating means, it is possible to keep the time for drying constant, thereby allowing the characteristics of an obtained optical film to be uniform.

The dyeing process is carried out by, for example, allowing a dichroic material to be adsorbed and oriented in a non-drawn or drawn film. Examples of a method for carrying out such a dyeing process include a method comprising stretching a non-drawn film in water or pure water, followed by immersing the drawn film in a dye solution contained in a bath, a method comprising immersing a non-drawn film in a dye solution contained in a bath, followed by stretching the film, and a method comprising stretching a non-drawn film in a dye solution contained in a bath.

The cross-linking process is carried out by, for example, immersing a film in a solution containing boric acid or borax. The cross-linking process can be carried out concurrently with the stretching process in a single step or multiple steps, thereby improving durability and stability of a long film. For example, in a case where the cross-linking process is carried out in two steps, it is possible to allow a stained film to be cross-linked to a certain extent in a first cross-linking step, thereby suppressing necking resulting from stretching as much as possible and enabling a polarizer with a higher degree of polarization and a wider width to be produced.

In the case of producing a polarizing film, examples of the film 21 to be used include films obtained by allowing iodine or dichroic dye to be adsorbed and oriented in polymer films such as polyvinyl alcohol-based films, partially formalized polyvinyl alcohol-based films, polyethylene terephthalate-based films, ethylene/vinyl acetate copolymer-based films, partially saponified films thereof, and cellulose-based films; and polyethylene type oriented films such as dehydrated polyvinyl alcohol and dehydrochlorinated polyvinyl chloride. Among them, polyvinyl alcohol-based films are generally used from the viewpoint of high orientation of iodine or dichroic dye in the dyeing process (which will be described later).

As materials for forming such polyvinyl alcohol-based films, polyvinyl alcohol (e.g., VF-9P75RS manufactured by KURARAY CO., LTD.) and derivatives thereof can be used. Examples of derivatives of polyvinyl alcohol include, in addition to polyvinyl formal and polyvinyl acetal, derivatives modified with olefins such as ethylene and propylene, unsaturated carboxylic acids such as acrylic acid, methacrylic acid, and crotonic acid, alkyl esters thereof, and acrylamide. Generally, polyvinyl alcohol having a degree of polymerization of about 2,000 to 10,000, preferably 2,000 to 5,000, and a degree of saponification of about 80 to 100 mol % is used.

The polyvinyl alcohol-based film may contain additives such as plasticizers. Examples of plasticizers include polyols and condensates thereof such as glycerol, diglycerol, triglycerol, ethylene glycol, propylene glycol, and polyethylene glycol. The amount of a plasticizer to be used is not particularly limited, but is preferably 20 wt % or less in the polyvinyl alcohol-based resin film.

A polarizer (that is, an optical film) obtained by the production method described above may be formed into a polarizing plate having a transparent protective layer on at least one surface thereof in the usual manner. The transparent protective layer can be prepared as a coating layer formed of a polymer or a laminated layer formed from a film. Transparent polymers or film materials for forming the transparent protective layer can be appropriately selected, but those having excellent transparency, mechanical strength, heat stability and water shielding properties are preferably used. Examples of such a material for forming the transparent protective layer include: polyester-based polymers such as polyethylene terephthalate and polyethylene naphthalate; cellulose-based polymers such as cellulose diacetate and cellulose triacetate; acrylic polymers such as polymethyl methacrylate; styrene-based polymers such as polystyrene and acrylonitrile/styrene copolymer (AS resin); and polycarbonate-based polymers. In addition, examples of a polymer for forming the transparent protective layer include polyolefins such as polyethylene, polypropylene, and polyolefins having a cyclo-type or norbornene structure; polyolefin-based polymers such as ethylene/propylene copolymer; vinyl chloride-based polymers; amide-based polymers such as nylon and aromatic polyamides; imide-based polymers; sulfone-based polymers; polyether sulfone-based polymers; polyether ether ketone-based polymers; polyphenylene sulfide-based polymers; vinyl alcohol-based polymers; vinylidene chloride-based polymers; vinyl butyral-based polymers; arylate-based polymers; polyoxymethylene-based polymers; epoxy-based polymers; and mixtures of two or more of these polymers.

The surface of the transparent protective film onto which the polarizer is not adhered (the surface of the transparent protective coating layer onto which the polarizer is not provided) may be subjected to treatment for forming a hard coating layer, anti-reflection treatment, anti-sticking treatment, or treatment for the purpose of diffusion or anti glare.

Hard coating treatment is carried out for, for example, preventing the surface of a polarizing plate from being scratched. A hard coating layer can be formed by, for example, applying onto the surface of the transparent protective film, a cured coating film excellent in hardness and slide properties by the use of an appropriate UV curable resin such as an acrylic resin or a silicone-based resin. Anti-reflection treatment is carried out to prevent external light from being reflected off the surface of a polarizing plate, and can be achieved by forming an anti-reflection film according to a conventional method. Anti-sticking treatment is carried out to prevent sticking to an adjacent layer.

Anti-glare treatment is carried out to prevent the occurrence of a phenomenon in which external light is reflected off the surface of a polarizing plate to interfere with the visual recognition of light passing through the polarizing plate. Such anti-glare treatment can be achieved by forming fine irregularities on the surface of the transparent protective film by an appropriate method such as surface roughening (e.g., sandblasting, embossing) or blending of transparent fine particles. Examples of such fine particles to be blended for forming fine irregularities on the surface of the transparent protective film include transparent fine particles having an average particle size of 0.5 to 50 μm, such as inorganic fine particles of silica, alumina, titania, zirconia, tin oxide, indium oxide, cadmium oxide, antimony oxide, and the like; and organic fine particles of crosslinked or non-crosslinked polymers. These inorganic fine particles may have conductivity. The amount of the fine particles to be used is generally in the range of about 2 to 50 parts by weight, preferably in the range of 5 to 25 parts by weight, with respect to 100 parts by weight of a transparent resin on the surface of which fine irregularities are to be formed. An anti-glare layer may also serve as a diffusion layer (which has the function of, for example, increasing a viewing angle) for diffusing light passing through a polarizing plate to increase a viewing angle etc.

It is to be noted that the anti-reflection layer, the anti-sticking layer, the diffusion layer, the anti-glare layer, and the like may be provided in the transparent protective film itself. Alternatively, each of the layers may be provided as an optical layer separately from the transparent protective layer.

Adhesion between the transparent protective film and the polarizer is carried out with an adhesive. Examples of such an adhesive include isocyanate-based adhesives, polyvinyl alcohol-based adhesives, gelatin-based adhesives, vinyl-based latexes, and water-based polyesters. The adhesive is generally used as an aqueous adhesive solution having a solid content of 0.5 to 60% by weight.

As described above, a polarizing plate is manufactured by laminating the transparent protective film and the polarizer together with such an adhesive described above. The adhesive can be applied onto either the transparent protective film or the polarizer or both. After the transparent protective film and the polarizer are laminated together with an adhesive, they are dried to form an adhesive layer comprising a dried coating layer. Lamination between the transparent protective film and the polarizer can be carried out with, for example, a roll laminator. The thickness of the adhesive layer is not particularly limited, but is generally in the range of about 0.05 to 5 μm.

It is to be noted that the method for producing an optical film according to the present invention is also preferably used as a method for producing a retardation film or the like comprising stretching a film and applying various solutions onto the film.

On the optical film of the present invention, other optical layers may further be laminated. No specific limitation is placed on an additional optical layer, and there can be used one optical layer, or two optical layers or more that is used in formation of a liquid crystal display or the like such as a reflection plate, a semipermeation plate, a retardation plate (including ½ or ¼ wavelength plate), A visual angle compensating film. Especially preferable is a polarizing plate obtained by further laminating a brightness enhancement film on a polarizing plate. In particular, a reflection type polarizing plate or a semipermeation-type polarizing plate in which a reflection plate or a semipermeation reflection plate is further laminated on a polarizing plate, an elliptic polarizing plate or a circular polarizing plate in which a phase difference plate is laminated on a polarizing plate, a wide field angle polarizing plate in which a visual angle compensating film is further laminated on a polarizing plate, or a polarizing plate in which a luminance improving film is further laminated on a polarizing plate is preferable.

A reflection-type polarizing plate is a plate in which a reflection layer is provided on a polarizing plate, is for forming a liquid crystal display device which is a type of reflecting and displaying incident light from a visible side (display side), and has an advantage that building-in of a light source such as back light can be omitted, and a liquid crystal display device is easily thinned. Formation of a reflection-type polarizing plate can be performed by an appropriate format such as a format of providing a reflection layer comprising a metal on one side of a polarizing plate via a transparent protecting layer, if necessary.

A reflection plate may be used by a reflection sheet on which a reflection layer is provided on an appropriate film like a transparent protecting film in place of a format of directly imparting to the transparent film of a polarizing plate. Since a reflection layer is usually made of a metal, a use aspect in the state where its reflection side is covered with a transparent protecting film or a polarizing plate is more preferable from a viewpoint of prevention of reduction in a reflectivity due to oxidation, consequently long term durability of an initial reflectivity, and avoidance of separate provision of a protecting layer.

A semi-permeation polarizing plate can be obtained by adopting a semi-permeation type reflection layer such as a half mirror which reflects light on a reflection layer and permeates light in the aforementioned plate. The semi-permeation polarizing plate is usually provided on a back side of a liquid crystal cell, and such a type of a liquid crystal display device can be formed that, when a liquid crystal display device is used in the relatively light atmosphere, incident light from a visible side (display side) is reflected to display an image and, in the relatively dark atmosphere, an image is displayed using a built-in light source such as back light built in a back side of a semi-permeation polarizing plate. That is, the semi-permeation polarizing plate is useful for forming such a type, of a liquid crystal display device that energy which is used in a light source such as back light can be saved, and the device can be used using a built-in light source also under the relatively dark atmosphere.

An elliptic polarizing plate or a circular plate in which a phase difference plate is further laminated on a polarizing plate will be explained. When a linearly polarized light is changed to elliptically polarized light or a circularly polarized light, or elliptically polarized light or circularly polarized light is changed to linearly polarized light, or a polarization direction of linearly polarized light is changed, a phase difference plate is used. In particular, as a phase difference plate for changing linearly polarized light to circularly polarized light, or changing circularly polarized light to linearly polarized light, a so-called ¼ wavelength plate (also referred to as λ/4 plate) is used. A ½ wavelength plate (also referred to as λ/2 plate) is usually used when a polarization direction of linearly polarized light is changed.

Elliptically polarizing plate is effectively used to give a monochrome display without above-mentioned coloring by compensating (preventing) coloring (blue or yellow color) produced by birefringence of a liquid crystal layer of a super twisted nematic (STN) type liquid crystal display. Furthermore, a polarizing plate in which three-dimensional refractive index is controlled may also preferably compensate (prevent) coloring produced when a screen of a liquid crystal display is viewed from an oblique direction. Circularly polarizing plate is effectively used, for example, when adjusting a color tone of a picture of a reflective type liquid crystal display that provides a colored picture, and it also has function of antireflection. For example, a retardation plate may be used that compensates coloring and viewing angle, etc. caused by birefringence of various wavelength plates or liquid crystal layers etc. Besides, optical characteristics, such as retardation, may be controlled using laminated layer with two or more sorts of retardation plates having suitable retardation value according to each purpose. As retardation plates, birefringence films formed by stretching films comprising suitable polymers, such as polycarbonates, polyvinyl alcohols, polystyrenes, poly methyl methacrylates, polypropylene; polyallylates and polyamides; oriented films comprising liquid crystal materials, such as liquid crystal polymer; and films on which an alignment layer of a liquid crystal material is supported may be mentioned. A retardation plate may be a retardation plate that has a proper phase difference according to the purposes of use, such as various kinds of wavelength plates and plates aiming at compensation of coloring by birefringence of a liquid crystal layer and of visual angle, etc., and may be a retardation plate in which two or more sorts of retardation plates is laminated so that optical properties, such as retardation, may be controlled.

The aforementioned elliptic polarizing plate or reflection-type elliptic polarizing plate is such that an appropriate combination of a polarizing plate or a reflection-type polarizing plate and a phase difference plate is laminated. Such the elliptic polarization plate can be formed by successively and separately laminating a (reflection-type) polarizing plate and a phase difference plate in a process for manufacturing a liquid crystal display device so that a combination of the (reflection-type) polarizing plate and the phase difference plate is obtained, and an optical member such as an elliptic polarizing plate which has been formed in advance as described above has an advantage that it is excellent in stability of quality and laminating workability, and an efficiency of manufacturing a liquid crystal display device can be improved.

A visual angle compensating film is a film for extending a field angle so that an image is seen relatively clearly even when a screen of a liquid crystal display device is seen not from a direction vertical to the screen but from a slightly slant direction. Such the visual angle compensating phase difference plate is such that an orientation layer of a liquid crystal polymer is supported on a phase difference plate, an oriented film such as a liquid crystal polymer, or a transparent substrate. In a normal phase difference plate, a polymer film having birefringence which has been monoaxially stretched in its surface direction is used, while in a phase difference plate used as a visual angle compensating film, a bidirectional stretched film such as a polymer film having birefringence which has been biaxially stretched in a surface direction, a polymer having birefringence which has been monoaxially stretched in a surface direction, is also stretched, and also stretched in a thickness direction, and has a controlled refractive index in a thickness direction, and a slantly oriented film is used. Examples of the slantly oriented film include a film obtained by adhering a thermally shrinking film to a polymer film, and subjecting the polymer film to stretching treatment or/and shrinking treatment under action of a shrinking force due to heating, and a film in which a liquid crystal polymer is slantly oriented. As a raw material polymer for a phase difference plate, the same polymer as that explained for the previous phase difference plate is used, and an appropriate polymer for the purpose of preventing coloration due to change in a visual confirmation angle based on a phase difference due to a liquid crystal cell, or extending a field angle for better visual confirmation can be used.

In addition, from a viewpoint of accomplishment of a wide field angle for better visual confirmation, an optical compensating phase difference plate in which an optically anisotropic layer comprising an oriented layer of a liquid crystal polymer, in particular, a slantly oriented layer of a discotic liquid crystal polymer is supported by a triacetylcellulose film can be preferably used.

A polarizing plate in which a polarizing plate and a luminance improving film are laminated is usually used by provision on a back side of a liquid crystal cell. The luminance improving film exhibits such the property that, when natural light is introduced by back light of a liquid crystal display device, or reflection from a back side, linearly polarized light having a prescribed polarization axis or circularly polarized light in a prescribed direction is reflected, and other light is permeated. In a polarizing plate in which the luminance improving film is laminated on a polarizing plate, light from a light source such as back light is introduced to obtain permeated light in the prescribed polarized state and, at the same time, light other than the aforementioned prescribed polarized state is reflected without permeation. Light reflected on a surface of this luminance improving film is inverted via a reflection layer provided on its rear side to introduce into the luminance improving film again, a part or all of this is permeated as light in the prescribed polarized state to increase an amount of light permeating through the luminance improving film and, at the same time, polarized light which is absorbed in a polarizer with difficulty is supplied to increase an amount of light which can be utilized in a liquid crystal display image display, thereby, a luminance can be improved. That is, when light is introduced through a polarizer from a back side of a liquid crystal cell by back light without using the luminance improving film, most of light having a polarization direction which is not consistent with a polarization axis of a polarizer is absorbed in a polarizer, and is not permeated through a polarizer.

The suitable films are used as the above-mentioned brightness enhancement film. Namely, multilayer thin film of a dielectric substance; a laminated film that has the characteristics of transmitting a linearly polarized light with a predetermined polarizing axis, and of reflecting other light, such as the multilayer laminated film of the thin film having a different refractive-index anisotropy; an aligned film of cholesteric liquid-crystal polymer; a film that has the characteristics of reflecting a circularly polarized light with either left-handed or right-handed rotation and transmitting other light, such as a film on which the aligned cholesteric liquid crystal layer is supported; etc. may be mentioned.

Therefore, in the brightness enhancement film of a type that transmits a linearly polarized light having the above-mentioned predetermined polarization axis, by arranging the polarization axis of the transmitted light and entering the light into a polarizing plate as it is, the absorption loss by the polarizing plate is controlled and the polarized light can be transmitted efficiently. On the other hand, in the brightness enhancement film of a type that transmits a circularly polarized light as a cholesteric liquid-crystal layer, the light may be entered into a polarizer as it is, but it is desirable to enter the light into a polarizer after changing the circularly polarized light to a linearly polarized light through a retardation plate, taking control an absorption loss into consideration. In addition, a circularly polarized light is convertible into a linearly polarized light using a quarter wavelength plate as the retardation plate.

Although an optical film having the optical layers laminated on the polarizing plate can be formed in the manufacturing process of, for example, liquid crystal displays by a method in which the optical layers are laminated one by one, a method in which the previously laminated optical layers are laminated on the polarizing plate is advantageous in that it can improve the quality stability of the optical film and the efficiency of assembly work of liquid crystal displays. Laminating is carried out by using an appropriate adhesion means such as a pressure-sensitive adhesive layer. In adhesion of the polarizing plate and other optical films, their optical axes may be arranged so that they have appropriate arrangement angles according to desired retardation characteristics etc.

On the optical film such as the polarizing plate mentioned above, an adhesive layer may be prepared for adhesion with other members, such as a liquid crystal cell etc. As pressure sensitive adhesive that forms adhesive layer is not especially limited, and, for example, acrylic type polymers; silicone type polymers; polyesters, polyurethanes, polyamides, polyethers; fluorine type and rubber type polymers may be suitably selected as a base polymer. Especially, a pressure sensitive adhesive such as acrylics type pressure sensitive adhesives may be preferably used, which is excellent in optical transparency, showing adhesion characteristics with moderate wettability, cohesiveness and adhesive property and has outstanding weather resistance, heat resistance, etc.

Moreover, an adhesive layer with low moisture absorption and excellent heat resistance is desirable. This is because those characteristics are required in order to prevent foaming and peeling-off phenomena by moisture absorption, in order to prevent decrease in optical characteristics and curvature of a liquid crystal cell caused by thermal expansion difference etc. and in order to manufacture a liquid crystal display excellent in durability with high quality.

The adhesive layer may contain additives, for example, such as natural or synthetic resins, adhesive resins, glass fibers, glass beads, metal powder, fillers comprising other inorganic powder etc., pigments, colorants and antioxidants. Moreover, it may be an adhesive layer that contains fine particle and shows optical diffusion nature.

Proper method may be carried out to attach an adhesive layer to the optical device or the optical film. As an example, about 10 to 40 weight % of the pressure sensitive adhesive solution in which a base polymer or its composition is dissolved or dispersed, for example, toluene or ethyl acetate or a mixed solvent of these two solvents is prepared. A method in which this solution is directly applied on a polarizing plate top or an optical film top using suitable developing methods, such as flow method and coating method, or a method in which an adhesive layer is once formed on a separator, as mentioned above, and is then transferred on a polarizing plate or an optical film may be mentioned.

An adhesive layer may also be prepared on each layer as a layer in which pressure sensitive adhesives with different composition or different kind etc. are laminated together. Thickness of an adhesive layer may be suitably determined depending on a purpose of usage or adhesive strength, etc., and generally is 1 to 500 μm, preferably 5 to 200 μm, and more preferably 10 to 100 μm.

A temporary separator is attached to an exposed side of an adhesive layer to prevent contamination etc., until it is practically used. Thereby, it can be prevented that foreign matter contacts adhesive layer in usual handling. As a separator, without taking the above-mentioned thickness conditions into consideration, for example, suitable conventional sheet materials that is coated, if necessary, with release agents, such as silicone type, long chain alkyl type, fluorine type release agents, and molybdenum sulfide may be used. As a suitable sheet material, plastics films, rubber sheets, papers, cloths, no woven fabrics, nets, foamed sheets and metallic foils or laminated sheets thereof may be used.

In addition, in the present invention, ultraviolet absorbing property may be given to the above-mentioned each layer, such as a polarizer for a polarizing plate, a transparent protective film and an optical film etc. and an adhesive layer, using a method of adding UV absorbents, such as salicylic acid ester type compounds, benzophenol type compounds, benzotriazol type compounds, cyano acrylate type compounds, and nickel complex salt type compounds.

An optical device having the hard-coated film of the present invention may be preferably used for manufacturing various equipments, such as liquid crystal display, etc. Assembling of a liquid crystal display may be carried out according to conventional methods. That is, a liquid crystal display is generally manufactured by suitably assembling several parts such as a liquid crystal cell, optical films and, if necessity, lighting system, and by incorporating driving circuit. In the present invention, except that an optical film by the present invention is used, there is especially no limitation to use any conventional methods. Also any liquid crystal cell of arbitrary type, such as TN type, and STN type, n type may be used.

Suitable liquid crystal displays, such as liquid crystal display with which the above-mentioned optical film has been located at one side or both sides of the liquid crystal cell, and with which a backlight or a reflector is used for a lighting system may be manufactured. In this case, the optical film by the present invention may be installed in one side or both sides of the liquid crystal cell. When installing the optical films in both sides, they may be of the same type or of different type. Furthermore, in assembling a liquid crystal display, suitable parts, such as diffusion plate, anti-glare layer, antireflection film, protective plate, prism array, lens array sheet, optical diffusion plate, and backlight, may be installed in suitable position in one layer or two or more layers.

Subsequently, organic electro luminescence equipment (organic EL display) will be explained. Generally, in organic EL display, a transparent electrode, an organic luminescence layer and a metal electrode are laminated on a transparent substrate in an order configuring an illuminant (organic electro luminescence illuminant). Here, an organic luminescence layer is a laminated material of various organic thin films, and much compositions with various combination are known, for example, a laminated material of hole injection layer comprising triphenylamine derivatives etc., a luminescence layer comprising fluorescent organic solids, such as anthracene; a laminated material of electronic injection layer comprising such a luminescence layer and perylene derivatives, etc.;

laminated material of these hole injection layers, luminescence layer, and electronic injection layer etc.

An organic EL display emits light based on a principle that positive hole and electron are injected into an organic luminescence layer by impressing voltage between a transparent electrode and a metal electrode, the energy produced by recombination of these positive holes and electrons excites fluorescent substance, and subsequently light is emitted when excited fluorescent substance returns to ground state. A mechanism called recombination which takes place in an intermediate process is the same as a mechanism in common diodes, and, as is expected, there is a strong non-linear relationship between electric current and luminescence strength accompanied by rectification nature to applied voltage.

Since the retardation plate and the polarizing plate have function polarizing the light that has entered as incident light from outside and has been reflected by the metal electrode, they have an effect of making the mirror surface of metal electrode not visible from outside by the polarization action. If a retardation plate is configured with a quarter wavelength plate and the angle between the two polarization directions of the polarizing plate and the retardation plate is adjusted to π/4, the mirror surface of the metal electrode may be completely covered.

Preferred examples of the invention are illustratively described in detail below. Unless otherwise stated, the materials, contents and so on as shown in the examples are not intended to limit the scope of the invention in any way and are intended for illustration purposes only.

### EXAMPLE 1

A polyvinyl alcohol (hereinafter, abbreviated as “PVA”) film having a thickness of 75 μm was continuously subjected to processes of swelling, dyeing, cross-linking, stretching, rinsing, and drying to produce a polarizing film according to the present invention. The PVA film was prepared by joining the tail end of one sheet of the film to the front end of an adjacent sheet of the film in a longitudinal direction thereof with a pressure-sensitive adhesive tape (that is, with a double-sided tape manufactured by Nitto Denko Corporation (No. 500)), thereby allowing a polarizing film to be continuously produced.

More specifically, first, the PVA film was fed into a production apparatus for carrying out a swelling process. In the production apparatus for swelling, the PVA film was immersed in water at a temperature of 25° C. to draw the PVA film in water so that the length of the PVA film was extended to 2.8 times the original length of the PVA film.

Next, after the completion of the swelling process, the PVA film was fed into a production apparatus for carrying out a dyeing process. In the production apparatus for dyeing, the PVA film was immersed in a dye solution to draw the PVA film in the dye solution so that the length of the PVA film was extended to 3.0 times the original length of the PVA film. The dye solution was prepared so that a finally obtained polarizing plate could have a transmittance of 43%. More specifically, the dye solution was prepared by adding a high concentration iodine solution to water at a temperature of 25° C.

The high concentration iodine solution was obtained by mixing water, potassium iodine, and iodine in a ratio of 90: 9: 1, and was used for adjusting the concentration of iodine in the dye solution.

Then, after the completion of the dyeing process, the PVA film was fed into a production apparatus for carrying out a cross-linking process. In the production apparatus for cross-linking, the PVA film was immersed in a cross-linking solution to draw the PVA film in the cross-linking solution so that the length of the PVA film was extended to 3.5 times the original length of the PVA Film. The cross-linking solution was prepared by adding 4 wt % of boric acid and 3 wt % of potassium iodine to water at a temperature of 60° C.

Then, after the completion of the cross-linking process, the PVA film was fed into a production apparatus for carrying out a stretching process. In the production apparatus for stretching, the PVA film was immersed in a solution to draw the PVA film in the solution so that the length of the PVA film was extended to 6.0 times the original length of the PVA film. The solution for stretching was prepared by adding 4 wt % of boric acid and 3 wt % of potassium iodine to water at a temperature of 60° C.

Then, after the completion of the stretching process, the PVA film was immersed in a 3 wt % aqueous potassium iodine solution at a temperature of 25° C. while keeping tension applied to the PVA film (rinsing process). In each of the treatment processes, the optical film production apparatus described above with reference to the embodiment of the present invention was used (see FIGS. 1 and 2). When the PVA film was fed into the production apparatus in each treatment process, the exit-side transport roll and the inlet-side transport roll were driven. At this time, when a joint between adjacent sheets of the PVA film was inserted into the production apparatus, the elevating rolls provided in the production apparatus were all moved up so that the joint was not brought into contact with the elevating rolls. Stretching of the PVA film was carried out utilizing the difference in circumferential velocity between the exit-side transport roll and the inlet-side transport roll. After the joint was passed through the production apparatus, the elevating rolls were moved down to again immerse the PVA film in the baths (see FIG. 2). After the completion of the rinsing process, the PVA film was taken out of the aqueous potassium iodine solution to dry it at 70° C. for 10 minutes (drying process).

In this way, a polarizing film according to the present invention was produced. In the Example 1, the time required for switching of the PVA film (that is, the time lapsed until adjacent sheets of the PVA film were joined end to end with a pressure-sensitive adhesive tape and the PVA film was again fed into the production apparatus) was 10 minutes, and it took one person to do the task. It is to be noted that the time required for joining adjacent sheets of the PVA film end to end with a pressure-sensitive adhesive tape was only 30 seconds. During joining adjacent sheets of the PVA film together, the PVA film was controlled by an accumulating roll to prevent loosening of the PVA film. The accumulating roll was provided immediately in front of the bath used for the swelling process. As described above, if the pressure-sensitive adhesive tape used for joining adjacent sheets of the PVA film together is immersed in the solution contained in each bath, it is dissolved in the solution and therefore a joint between adjacent sheets of the PVA film is separated. However, in the Example 1, a joint between adjacent sheets of the PVA film was transported without being immersed in the solution in each bath, and therefore the separation of the joint did not occur and the pressure-sensitive adhesive used in the joint was not eluted, thereby preventing contamination of the solution in each bath and the transport rolls.

### EXAMPLE 2

On both surfaces of the polarizing film produced in the Example 1, a triacetyl cellulose (hereinafter, abbreviated as “TAC”) film was laminated continuously. Before a sheet of the TAC film was exhausted, the tail end of the sheet of the TAC film was joined to the front end of an adjacent sheet of the TAC film with a pressure-sensitive adhesive tape (that is, with a double-sided tape manufactured by Nitto Denko Corporation (No. 500)).

Then, the polarizing film having the TAC film adhered on both surfaces thereof was dried using the optical film production apparatus described above with reference to the embodiment of the present invention (see FIGS. 3 and 4). More specifically, the polarizing film with TAC film was fed into the production apparatus by driving the exit-side transport roll and the inlet-side transport roll. At this time, when a joint between adjacent sheets of the TAC film was inserted into the production apparatus, the upper elevating rolls were all moved up at the same time and the lower elevating rolls were all moved down at the same time to provide a straight film transport path to prevent contact between the joint and the upper and lower elevating rolls.

After the joint was passed through the production apparatus, the upper elevating rolls were all moved down at the same time and the lower elevating rolls were all moved up at the same time to increase the length of the transport path of the polarizing film with TAC film to dry it (see FIG. 4). It is to be noted that the polarizing film with TAC film was dried at 75° C. for 10 minutes. In this way, a polarizing plate according to the Example 2 was produced.

### EXAMPLE 3

A polarizing plate according to the Example 3 was produced in the same manner as in the Example 2 except that the movements of the upper and lower elevating rolls provided in the production apparatus were changed. More specifically, each of the upper and lower elevating rolls through which a joint of the TAC film had been passed was moved down or up one after another to provide a film transport path along which the polarizing film with TAC film was meandered up and down, thereby allowing a polarizing plate to be produced continuously.

### Comparative Example 1

A polarizing film was produced in the same manner as in the Example 1 except that one sheet of the PVA film was manually threaded through a film transport path of all the treatment processes carried out by immersing the film in a solution and then the tail end of the sheet was joined to the front end of the PVA film with a pressure-sensitive adhesive tape (that is, with a double-sided tape manufactured by Nitto Denko Corporation (No. 500)) in midair and that a joint of the PVA film was immersed in the baths. It is to be noted that in a case where a joint between adjacent sheets of the PVA film is immersed in the baths while the PVA film is threaded through the film transport path, separation of the joint is likely to occur. If separation of the joint occurs, it is necessary to again thread the PVA film through the film transport path from a first treatment process.

The time required for switching of the PVA film was 30 minutes, and it took two persons to do the task.

### Comparative Example 2

A polarizing plate was produced in the same manner as in the Example 2 except that even when a joint of the TAC film was inserted into the production apparatus for drying, the production apparatus for drying did not make the transport path of the polarizing film with TAC film straight, that is, drying was carried out while maintaining a state where the upper elevating rolls were still located at lower position and the lower elevating rolls were still located at upper position.

Appearance Evaluation

Appearance evaluation was performed on the polarizing plates obtained in the Examples 2 and 3 and Comparative Example 2. More specifically, each of the polarizing plates obtained from an area between a joint of the TAC film and a position 2 m posterior to the joint in a film transport direction was visually observed to count the number of defects (dents, scratches) believed to be due to the joint. As a result, the polarizing plate of each of the Examples 2 and 3 had one defect and it was confirmed that these polarizing plates had very good appearance. On the other hand, the polarizing plate of the Comparative Example 2 had 18 defects, thereby significantly reducing yield.

Film Loss Caused by Abnormal Optical Characteristics Among the polarizing plates produced in each of the Examples 2 and 3 and the Comparative Example 2, two polarizing plates obtained from areas close to each other were selected as samples.

These two polarizing plates were superposed so that their absorption axes were parallel to each other to determine a value b (parallel value b) in accordance with CIELAB color system defined in JIS Z 8729 with a spectrophotometer (“Dot-3C” manufactured by Murakami Color Research Laboratory). When the polarizing plate had a value b without a range of 6±0.2, the polarizing plate was rejected. Further, the ratio of rejected polarizing plates with respect to the total polarizing plates produced (hereinafter, simply referred to as a “film loss ratio”) was calculated. As a result, the film loss ratios of the polarizing plates of the Examples 2 and 3 and the Comparative Example 2 were 2.56%, 0.13%, and 0.13%, respectively.

As seen from the evaluation results, the polarizing plates of the Examples 2 and 3 had few defects, and were at a level suitable for practical use. The film loss ratio of the polarizing plates of the Example 2 was slightly high, but its impact on the total production was small. On the other hand, the polarizing plates of the Comparative Example 2 had many defects, and most of them were not at a level suitable for practical use.

What is claimed is:

1. A method for producing an optical film, comprising carrying out a given process by allowing a film having a joint to continuously pass through the given process while meandering the film to extend the length of a film transport path, wherein when the joint of the film passes through a given position in the given process, the film transport path is made straight to allow the joint to pass through the given position without meandering the film.

2. The method for producing an optical film according to claim 1, wherein the film transport path is sequentially made straight just before the joint of the film passes through the given position.

3. The method for producing an optical film according to claim 1, wherein the film is sequentially meandered just after the joint of the film has passed through the given position.

4. The method for producing an optical film according to claim 3, wherein the film is meandered while keeping at least either tension applied to the film or the staying time of the film constant.

5. The method for producing an optical film according to claim 1, wherein the given process is a process of immersion in a solution.

6. The method for producing an optical film according to claim 1, wherein the given process is a drying process.

7. The method for producing an optical film according to claim 5, wherein the process of immersion in a solution includes a dyeing process or a stretching process.

8. An apparatus for producing an optical film, comprising
a pair of transport means for transporting in a predetermined direction, a film having a joint to allow the film to continuously pass through a given process;
an elevating means which is provided between the pair of transport means and which is moved up or down to meander the film up and down; and
a control means for controlling the up and down movements of the elevating means, wherein when the joint of the film passes through a given position in the given process, the control means moves up or down the elevating means to provide a straight film transport path to allow the joint to pass through the given position without meandering the film, and wherein after the joint has passed through the given position, the control means moves up or down the elevating means to provide a film transport path along which the film is meandered up and down.

9. The apparatus for producing an optical film according to claim 8, wherein the control means sequentially moves up or down the elevating means through which the joint of the film is going to pass to provide the straight film transport path.

10. The apparatus for producing an optical film according to claim 8, wherein the control means sequentially moves up or down the elevating means through which the joint of the film has passed to meander the film up and down.

11. The apparatus for producing an optical film according to claim 8, further comprising an accumulating means.

12. The apparatus for producing an optical film according to claim 8, wherein the elevating means has a curved surface with which the film is to be brought into contact.

13. An optical film obtained by carrying out a given process by allowing a film having a joint to continuously pass through the given process while meandering the film to extend the length of a film transport path, wherein when the joint of the film passes through a given position in the given process, the film transport path is made straight to allow the joint to pass through the given position without meandering the film, and wherein after the joint has passed through the given position, the film is meandered up and down along the film transport path.
